(19) United States
(12) Patent Application Publication
(10) Pub. No.: US 2014/0151104 A1
(43) Pub. Date: Jun. 5, 2014

(54) ELECTRONIC COMPONENT EMBEDDED SUBSTRATE AND MANUFACTURING METHOD THEREOF

(71) Applicant: SAMSUNG ELECTRO-MECHANICS CO., LTD., SUWON (KR)

(72) Inventors: Yul Kyo CHUNG, YONGIN (KR); DOO HWAN LEE, DAEJEON (KR); SEUNG EUN LEE, SUNGNAM (KR); YEE NA SHIN, SUWON (KR)

(73) Assignee: SAMSUNG ELECTRO-MECHANICS CO., LTD., SUWON (KR)

(21) Appl. No.: 14/090,469

(22) Filed: Nov. 26, 2013

(30) Foreign Application Priority Data
Dec. 4, 2012 (KR) 10-2012-0139727

(51) Int. Cl. H05K 1/18; H05K 3/30

(52) U.S. Cl. CPC H05K 1/186; H05K 3/306
USPC 174/260; 29/837

(57) ABSTRACT

The present invention relates to an electronic component embedded substrate including: a cavity formed in at least one insulating layer provided inside the electronic component embedded substrate; an electronic component having at least a portion inserted in the cavity; and a cavity plating portion formed on a surface of the cavity opposite to at least one surface of the electronic component, and can improve electrical connectivity between an external electrode and a via even when the size of the external electrode of the electronic component is reduced than before.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2012-0139727, entitled filed Dec. 4, 2012, which is hereby incorporated by reference in its entirety into this application.

### BACKGROUND OF THE INVENTION

1. Field of the Invention

The present invention relates to an electronic component embedded substrate.

2. Description of the Related Art

As the recently released mobile devices such as smartphones and tablet PCs have been dramatically improved in performance and demanded to have high portability, studies on miniaturization, slimming, and high performance of electronic components used in these mobile devices have been continuously conducted.

Here, since an electronic component embedded substrate disclosed in Patent Document 1 etc. can secure a space for mounting extra components on its surface by embedding electronic components in a substrate, it has been highlighted as a way of implementing the miniaturization, slimming, and high performance of the electronic components mounted in the mobile devices.

In particular, as the performance of semiconductor chips is improved, stability of power supplied to the semiconductor chips is considered as important. For this, a decoupling capacitor or a bypass capacitor is provided between the semiconductor chip and a power supply line to remove noise of power and supply a stable current to the semiconductor chip in a situation in which a power supply current is being changed suddenly.

At this time, when mounting the semiconductor chip on the capacitor embedded substrate, since a distance between the decoupling capacitor and the semiconductor chip is minimized, it is possible to implement miniaturization and slimming while stably supplying power to the high performance semiconductor chip.

Meanwhile, according to Patent Document 1, a method of fixing a capacitor after processing a cavity in a position where an electronic component is to be inserted, embedding the electronic component by thermocompression using an insulator, processing a micro via hole with laser, and achieving electrical connection through plating is disclosed.

That is, in order to electrically connect between the electronic component embedded in a substrate and a circuit pattern provided on a surface of the substrate, a method of processing a via hole using laser and filling a conductive material in the via hole by a method such as plating has been commonly applied.

According to this common method, minimum conditions on the area of a via contact which is to be formed in the embedded electronic component can be determined according to factors such as placing tolerance generated when the electronic component is embedded in the substrate, via hole processing tolerance, and via hole size.

However, since the size of the via contact should be reduced according to a reduction in the size of the electronic component, as the electronic component becomes smaller, a matching error of the via and the electronic component is emerged as a serious problem.

### RELATED ART DOCUMENT

### Patent Document

Patent Document 1: Korean Patent Laid-open Publication No. 2007-0101183

### SUMMARY OF THE INVENTION

The present invention has been invented in order to overcome the above-described problems and it is, therefore, an object of the present invention to provide an electronic component embedded substrate that can improve electrical connectivity of an electronic component embedded in a substrate.

Further, it is another object of the present invention to provide a method of manufacturing an electronic component embedded substrate that can improve electronic connectivity of an electronic component embedded in a substrate.

In accordance with one aspect of the present invention to achieve the object, there is provided an electronic component embedded substrate having an electronic component embedded therein, including: a cavity formed in at least one insulating layer provided inside the electronic component embedded substrate; an electronic component having at least a portion inserted in the cavity; and a cavity plating portion formed on a surface of the cavity opposite to at least one surface of the electronic component.

At this time, an external electrode may be provided on a side surface of the electronic component, and the electronic component embedded substrate may further include a conductive filling portion formed by filling a conductive material between the cavity plating portion and the external electrode to electrically connect between the cavity plating portion and the external electrode.

Further, the electronic component embedded substrate may further include a via having one surface in contact with at least one area selected from at least a portion of the external electrode, at least a portion of the conductive filling portion, and at least a portion of the cavity plating portion.

Further, the external electrode may consist of at least two electrodes provided on a surface of the electronic component to be separated from each other, disconnecting portions may be formed in the cavity plating portion connected to the electrodes to electrically isolate the electrodes from each other, and a conductive filling portion may be filled between the respective cavity plating portions and the respective electrodes electrically separated by the disconnecting portions.

Further, an insulating material may be filled in a space between the electrodes, between the disconnecting portions, and between the conductive filling portions.

Further, the electronic component embedded substrate may further include a metal pattern provided on a surface of the insulating layer and electrically connected to the cavity plating portion and a via having one surface in contact with at least one area selected from at least a portion of the external electrode, at least a portion of the conductive filling portion, at least a portion of the cavity plating portion, and at least a portion of the metal pattern.

At this time, the external electrode may consist of at least two electrodes provided on a surface of the electronic component to be separated from each other, disconnecting portions may be formed in the cavity plating portion connected to the electrodes to electrically isolate the electrodes from each other, and a conductive filling portion may be filled between the respective cavity plating portions and the respective electrodes electrically separated by the disconnecting portions.

Further, an insulating material may be filled in a space between the electrodes, between the disconnecting portions, and between the conductive filling portions.

Further, a plurality of electronic components may be inserted in the cavity, and at least two of the plurality of electronic components may be connected in parallel.

Meanwhile, an external electrode may be provided on a side surface of the electronic component, and the cavity plating portion and the external electrode may be in contact with each other to be electrically connected to each other.

In this case, the electronic component embedded substrate may further include a via having one surface in contact with at least one area selected from at least a portion of the external electrode and at least a portion of the cavity plating portion.

Further, the external electrode may consist of at least two electrodes provided on a surface of the electronic component to be separated from each other, and disconnecting portions may be formed in the cavity plating portion connected to the electrodes to electrically isolate the electrodes from each other.

Further, an insulating material may be filled in a space between the electrodes and between the disconnecting portions.

Further, the electronic component embedded substrate may further include a metal pattern provided on a surface of the insulating layer and electrically connected to the cavity plating portion and a via having one surface in contact with at least one area selected from at least a portion of the external electrode, at least a portion of the cavity plating portion, and at least a portion of the metal pattern.

At this time, the external electrode may consist of at least two electrodes provided on a surface of the electronic component to be separated from each other, and disconnecting portions may be formed in the cavity plating portion connected to the electrodes to electrically isolate the electrodes from each other.

Further, an insulating material may be filled in a space between the electrodes and between the disconnecting portions.

In accordance with another aspect of the present invention to achieve the object, there is provided an electronic component embedded substrate in which an electronic component including a hexahedral body portion and two external electrodes which cover opposite surfaces of the body portion is embedded, including: a cavity formed in at least one insulating layer provided inside the electronic component embedded substrate; and a cavity plating portion formed on a surface of the cavity opposite to the external electrode.

In accordance with another aspect of the present invention to achieve the object, there is provided an electronic component embedded substrate including: a first insulating layer having a first metal pattern on a lower surface and a second metal pattern on an upper surface and including a cavity passing through the upper surface and the lower surface; an electronic component having at least one external electrode on a surface and having at least a portion inserted in the cavity; a cavity plating portion formed on a surface of the cavity opposite to the external electrode to be electrically connected to at least one of the first metal pattern and the second metal pattern; a conductive filling portion formed by filling a conductive material between the cavity plating portion and the external electrode; a second insulating layer for covering exposed surfaces of the first metal pattern, the first insulating layer, the cavity plating portion, the conductive filling portion, and the electronic component; a first circuit pattern formed on a surface of the second insulating layer; and a via having one surface in contact with at least one area selected from at least a portion of the external electrode, at least a portion of the conductive filling portion, at least a portion of the cavity plating portion, and at least a portion of the first metal pattern portion in contact with the cavity plating portion, and the other surface in contact with the first circuit pattern.

At this time, the electronic component may have at least two external electrodes formed in separated areas on a surface of the electronic component, disconnecting portions may be formed in the cavity plating portion connected to the external electrodes to electrically isolate the electrodes from each other, and the conductive filling portion may be filled between the respective cavity plating portions and the respective external electrodes electrically separated by the disconnecting portions.

Further, a material of the second insulating layer may be filled in a space between the external electrodes, between the disconnecting portions, and between the conductive filling portions.

Further, the electronic component embedded substrate may further include a fifth via having one surface in contact with at least a portion of the first metal pattern except the portion in contact with the cavity plating portion, and the other surface in contact with at least a portion of the first circuit pattern.

Further, the electronic component embedded substrate may further include a third insulating layer for covering the exposed surfaces of the first insulating layer, the cavity plating portion, the conductive filling portion, and the electronic component; a second circuit pattern formed on a surface of the third insulating layer; and a third via having one surface in contact with at least one area selected from at least a portion of the external electrode, at least a portion of the conductive filling portion, at least a portion of the cavity plating portion, and at least a portion of the second metal pattern portion in contact with the cavity plating portion, and the other surface in contact with the second circuit pattern.

At this time, at least one of a material of the first insulating layer and a material of the second insulating layer may be filled in a space between the external electrodes, between the disconnecting portions, and between the conductive filling portions.

Further, the electronic component embedded substrate may further include a sixth via having one surface in contact with at least a portion of the second metal pattern except the portion in contact with the cavity plating portion, and the other surface in contact with at least a portion of the second circuit pattern.

In accordance with another aspect of the present invention to achieve the object, there is provided a method of manufacturing an electronic component embedded substrate having an electronic component embedded therein, including the steps of: (A) forming a cavity in at least one insulating layer provided inside the electronic component embedded substrate and forming a cavity plating portion by plating a conductive material on a surface of the cavity; and (B) inserting at least a portion of the electronic component in the cavity.

At this time, the method of manufacturing an electronic component embedded substrate may further include the step of filling a conductive material in a space between the electronic component and the cavity plating portion after the step (B).

Further, the step (A) may include the steps of: (A1) forming a temporary remaining portion in a portion of the area in which the cavity is to be formed by processing a first temporary cavity having a “⊂” shape and a second temporary cavity having a shape symmetrical to the first temporary cavity to face each other while being separated from each other by a predetermined interval; (A2) plating a conductive material on surfaces of the first temporary cavity and the second temporary cavity; and (A3) removing the temporary remaining portion.

Further, the step (A) may include the steps of: (a1) forming a third temporary cavity in an area except a first projecting portion formed by projecting the insulating layer in the direction of a surface facing one surface of the cavity and a second projecting portion formed to be symmetrical to the first projecting portion on a surface facing the surface on which the first projecting portion is formed; (a2) plating a conductive material on a surface of the third temporary cavity; and (a3) removing portions of the first projecting portion and the second projecting portion.

In accordance with another aspect of the present invention to achieve the object, there is provided a method of manufacturing an electronic component embedded substrate, including the steps of: (a) providing a first insulating layer having a first metal pattern on a lower surface and a second metal pattern on an upper surface; (b) forming a cavity in the first insulating layer and forming a cavity plating portion electrically connected to at least one of the first metal pattern and the second metal pattern by plating a conductive material on a surface of the cavity; (c) attaching a detach film to a lower surface of the first metal pattern; (d) attaching a lower surface of an electronic component to the detach film by inserting at least a portion of the electronic component having a plurality of external electrodes on a surface; (e) forming a conductive filling portion by filling a conductive material between the cavity plating portion and the external electrodes; (f) forming a third insulating layer by applying an insulating material on exposed surfaces of the second metal pattern, the first insulating layer, the cavity plating portion, the conductive filling portion, and the electronic component; (g) processing a via hole, which exposes at least one area selected from at least a portion of the external electrodes, at least a portion of the conductive filling portion, at least a portion of the cavity plating portion, and at least a portion of the second metal pattern portion in contact with the cavity plating portion, through the third insulating layer; and (h) filling a conductive material in the via hole and forming a second circuit pattern on an upper surface of the third insulating layer.

At this time, the step (b) may include the steps of: (b1) forming a temporary remaining portion in a portion of the area in which the cavity is to be formed by processing a first temporary cavity having a “⊂” shape and a second temporary cavity having a shape symmetrical to the first temporary cavity to face each other while being separated from each other by a predetermined interval; (b2) plating a conductive material on surfaces of the first temporary cavity and the second temporary cavity; and (b3) removing the temporary remaining portion.

Further, the step (b) may include the steps of: (b1′) forming a third temporary cavity in an area except a first projecting portion formed by projecting the insulating layer in the direction of a surface facing one surface of the cavity and a second projecting portion formed to be symmetrical to the first projecting portion on a surface facing the surface on which the first projecting portion is formed; (b2′) plating a conductive material on a surface of the third temporary cavity; and (b3′) removing portions of the first projecting portion and the second projecting portion.

In accordance with another aspect of the present invention to achieve the object, there is provided a method of manufacturing an electronic component embedded substrate, including the steps of: (f1) forming a third insulating layer by applying an insulating material on exposed surfaces of a second metal pattern, a first insulating layer, a cavity plating portion, a conductive filling portion, and an electronic component; (f2) forming a second insulating layer by applying an insulating material on the exposed surfaces of a first metal pattern, the first insulating layer, the cavity plating portion, the conductive filling portion, and the electronic component after removing a detach film; (g1) forming a first via passing through the second insulating layer and a first circuit pattern provided on a lower surface of the second insulating layer to be connected to the first via; and (g2) forming a third via passing through the third insulating layer and a second circuit pattern provided on an upper surface of the third insulating layer to be connected to the third via, wherein one surface of the first via is in contact with at least one area selected from at least a portion of external electrodes, at least a portion of the conductive filling portion, at least a portion of the cavity plating portion, and at least a portion of the first metal pattern portion in contact with the cavity plating portion, and one surface of the third via is in contact with at least one area selected from at least a portion of the external electrodes, at least a portion of the conductive filling portion, at least a portion of the cavity plating portion, and at least a portion of the second metal pattern portion in contact with the cavity plating portion.

At this time, the step (d) may be performed to attach the lower surface of the electronic component to the detach film by inserting a plurality of electronic components in the cavity.

Further, at least two of the plurality of electronic components may be connected in parallel.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view schematically showing an electronic component embedded substrate in accordance with an embodiment of the present invention;

FIG. 2 is a plan view showing the surface taken along line I-I′ of FIG. 1 in the electronic component embedded substrate in accordance with an embodiment of the present invention;

FIG. 3 is a plan view showing the surface taken along line I-I′ of FIG. 1 in an electronic component embedded substrate in accordance with another embodiment of the present invention;

FIG. 4 is a plan view showing the surface taken along line I-I′ of FIG. 1 in an electronic component embedded substrate in accordance with still another embodiment of the present invention;

FIGS. 5a to 5i are process diagrams schematically showing a method of manufacturing an electronic component embedded substrate in accordance with an embodiment of the present invention, wherein

FIG. 5a is a cross-sectional view schematically showing the state in which a first metal pattern and a second metal pattern are formed on a first insulating layer,

FIG. 5b is a cross-sectional view schematically showing the state in which a cavity is formed in the first insulating layer,

FIG. 5c is a cross-sectional view schematically showing the state in which a cavity plating portion is formed in the cavity,

FIG. 5d is a cross-sectional view schematically showing the state in which a detach film is attached to the first metal pattern,

FIG. 5e is a cross-sectional view schematically showing the state in which an electronic component is inserted in the cavity,

FIG. 5f is a cross-sectional view schematically showing the state in which a conductive filling portion is formed,

FIG. 5g is a cross-sectional view schematically showing the state in which a third insulating layer is formed,

FIG. 5h is a cross-sectional view schematically showing the state in which a second insulating layer is formed, and

FIG. 5i is a cross-sectional view schematically showing the state in which first to sixth vias, a first circuit pattern, and a second circuit pattern are formed;

FIGS. 6a to 6d are process diagrams schematically showing the process of forming the cavity having the cavity plating portion in the first insulating layer in the method of manufacturing an electronic component embedded substrate in accordance with an embodiment of the present invention, wherein

FIG. 6a is a plan view schematically showing the state in which a first temporary cavity and a second temporary cavity are formed,

FIG. 6b is a plan view schematically showing the state in which a resist portion is formed,

FIG. 6c is a plan view schematically showing the state in which a plating process is performed, and

FIG. 6d is a plan view schematically showing the state in which a temporary remaining portion and the resist portion are removed; and

FIGS. 7a to 7c are process diagrams schematically showing a process of forming a cavity having a cavity plating portion in a first insulating layer, wherein

FIG. 7a is a plan view schematically showing the state in which a first projecting portion and a second projecting portion are formed,

FIG. 7b is a plan view schematically showing the state in which a plating process is performed, and

FIG. 7c is a plan view schematically showing the state in which the first projecting portion and the second projecting portion are removed.

### DETAILED DESCRIPTION OF THE PREFERABLE EMBODIMENTS

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art. Like reference numerals refer to like elements throughout the specification.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

Hereinafter, configurations and operational effects of the present invention will be described in detail with reference to the accompanying drawings.

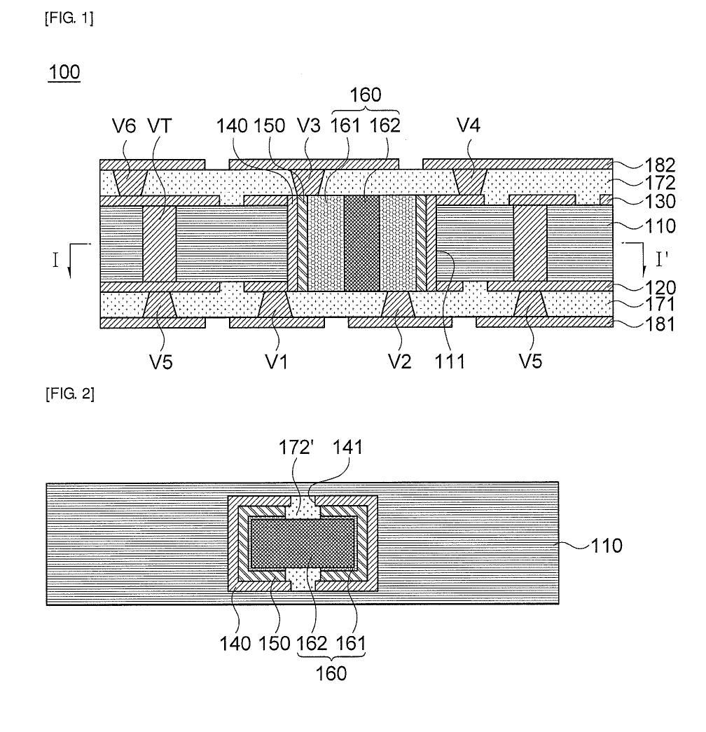

FIG. 1 is a view schematically showing an electronic component embedded substrate 100 in accordance with an embodiment of the present invention.

Referring to FIG. 1, the electronic component embedded substrate 100 in accordance with an embodiment of the present invention may include a first insulating layer 110 in which a cavity 111 is formed, a cavity plating portion 140 formed on a surface of the cavity 111, and an electronic component 160.

The first insulating layer 110 may be implemented with a common insulating material and may be implemented as a core board such as CCL.

Metal patterns 120 and 130 may be formed on at least one surface of the first insulating layer 110.

Referring to FIG. 1, it will be understood that a first metal pattern 120 is formed on a lower surface of the first insulating layer 110 and a second metal pattern 130 is formed on an upper surface of a second insulating layer 171.

At this time, when forming the cavity 111 or a through via hole for implementing a through via VT using CO₂ laser, the first metal pattern 120 and the second metal pattern 130 may perform a role of a kind of mask.

Of course, the via hole or the cavity 111 may be formed using YAG laser.

The electronic component 160, which is inserted in the cavity 111, may be a passive element such as a capacitor, a resistor, an inductor, or a filter or an active element such as IC.

Particularly, when embedding the electronic component 160 such as a capacitor, which has an external electrode 161 on a surface or a side surface, in a substrate, it is difficult to secure a sufficient area for implementing electrical connection in the electronic component 160.

For example, when processing the via hole using CO₂ laser, since a via contact area of about 150 μm is required and a placing tolerance of about 50 μm generated when mounting an electronic component may occur, it is required to secure a via contact size of at least 200 μm.

In a capacitor having a size of 1.0×0.5 mm which is widely used in recent times, since one side size of an external electrode may be implemented as greater than 200 μm, there is no big problem with application of a conventional common method.

However, a width of the external electrode 161 of a chip capacitor such as a small-sized multilayer ceramic capacitor (MLCC) is only about 100 to 200 μm in case of a 0603 chip (600 μm×300 μm) and only about 70 to 140 μm in case of a 0402 chip (400 μm×200 μm).

However, when processing the via hole using CO₂ laser, since a via contact width of at least 200 μm is required, it is extremely difficult to embed this small-sized MLCC etc. in a substrate and implement electrical connection using a via.

That is, since an error may occur due to problems such as placing tolerance, via hole processing tolerance, and via diameter of the electronic component 160, this error rate may emerge as a more serious problem as the size of the electronic component 160 decreases.

In order to overcome this problem, in the electronic component embedded substrate 100 in accordance with an embodiment of the present invention, the cavity plating portion 140 is formed on the surface of the cavity 111.

That is, in the prior art, since the electrical connection of the electronic component 160 is implemented by bringing a via in contact with a portion of an upper surface or a lower surface of the electronic component 160, the problem is caused when the area of the via contact is reduced. But it is possible to overcome the conventional problem by securing the electrical connection even by a path through which the electronic component 160 passes through the cavity plating portion 140. Particularly, the MLCC etc. have a rectangular parallelepiped-shaped body portion 162 including a magnetic body and an internal electrode and two external electrodes 161 which cover all of both surfaces facing each other and portions of the remaining side surfaces. It is possible to maximize an effect when this MLCC is inserted in the cavity 111 of the electronic component embedded substrate 100 in accordance with an embodiment of the present invention to electrically connect the external electrode 161 and the cavity plating portion 140.

At this time, the cavity plating portion 140 and the electronic component 160 may be implemented to be in direct contact with each other when precisely controlling the size of the cavity 111, the size of the electronic component 160, the thickness of the cavity plating portion 140, etc.

Further, if this precise control is difficult, the cavity plating portion 140 and the electronic component 160 may be implemented to have a predetermined clearance therebetween. In this case, a conductive filling portion 150 may be formed by filling a conductive material between the cavity plating portion 140 and the electronic component 160 to secure electrical connectivity between the cavity plating portion 140 and the electronic component 160.

Meanwhile, the cavity plating portion 140 may be in contact with the first metal pattern 120, the second metal pattern 130, etc. formed on the surface of the first insulating layer 110.

Therefore, in case of the electronic component embedded substrate 100 in accordance with an embodiment of the present invention, in forming the via, it is possible to secure a space as much as at least the thickness of the cavity plating portion 140. Furthermore, it is possible to expand the via contact to the conductive filling portion 150 and the first metal pattern 120 or the second metal pattern 130.

Accordingly, unlike the prior art in which the problem is caused when the width of the external electrode 161 is reduced since the via should be in contact with the external electrode 161 of the electronic component 160, in the electronic component embedded substrate 100 in accordance with an embodiment of the present invention, since the area to which the via can be connected can be remarkably expanded than the prior art, it is possible to overcome the conventional problem.

Continuously referring to FIG. 1, the electronic component embedded substrate 100 in accordance with an embodiment of the present invention may include a second insulating layer 171, a third insulating layer 172, a first circuit pattern 181, a second circuit pattern 182, first to sixth vias V1 to V6, a through via VT, etc.

The second insulating layer 171, which is formed under the first insulating layer 110, may cover the exposed surfaces of the first metal pattern 120, the first insulating layer 110, the cavity plating portion 140, the conductive filling portion 150, and the electronic component 160.

The third insulating layer 172, which is formed on the first insulating layer 110, may cover the exposed surfaces of the second metal pattern 130, the first insulating layer 110, the cavity plating portion 140, the conductive filling portion 150, and the electronic component 160.

The first circuit pattern 181 may be formed on a lower surface of the second insulating layer 171, and the second circuit pattern 182 may be formed on an upper surface of the third insulating layer 172.

The first to fourth vias V1 to V4 perform a function of electrically connecting the electronic component 160 embedded in the substrate to other components.

At this time, the first via V1 and the second via V2 may be connected to anywhere in a wide area consisting of the external electrode 161 of the electronic component 160, the conductive filling portion 150, the cavity plating portion 140, and the first metal pattern 120 portion in contact with the cavity plating portion 140.

Further, the third via V3 and the fourth via V4 may be connected to anywhere in a wide area consisting of the external electrode 161 of the electronic component 160, the conductive filling portion 150, the cavity plating portion 140, and the second metal pattern 130 portion in contact with the cavity plating portion 140.

That is, as shown in FIG. 1, it is possible to be in direct contact with the external electrode 161 of the electronic component 160 like the second via V2 or in contact with a portion of the external electrode 161, the conductive filling portion 150, and the cavity plating portion 140 like the third via V3. Further, it is possible to implement the electrical connection of the electronic component 160 by being in contact with the first metal pattern 120 portion in contact with the cavity plating portion 140 like the first via V1 or in contact with the second metal pattern 130 portion in contact with the cavity plating portion 140 like the fourth via V4.

Meanwhile, in addition to the above-described first to fourth vias V1 to V4, the fifth via V5 connected between the first metal pattern 120 and the first circuit pattern 181, the sixth via V6 connected between the second metal pattern 130 and the second circuit pattern 182, and the through via VT passing through the first insulating layer 110 to directly connect the first metal pattern 120 and the second metal pattern 130 may be further provided.

FIG. 2 is a plan view showing the surface taken along line I-I′ of FIG. 1 in the electronic component embedded substrate 100 in accordance with an embodiment of the present invention.

Referring to FIG. 2, it will be understood that the electronic component 160 having the two external electrodes 161 which respectively cover the both side surfaces of the body portion 161 and are separated from each other on the other side surfaces is positioned in the center of the cavity 111, the two conductive filling portions 150 are respectively in direct contact with the surfaces of the external electrodes 161, and the two cavity plating portions 140 are formed on the surface of the cavity 111 to be respectively in contact with the surfaces of the conductive filling portions 150.

That is, when the electronic component 160 is a capacitor, it is needed to be configured as shown in FIG. 2 since the both electrodes should be electrically isolated from each other.

At this time, a disconnecting portion 141 may be provided to secure insulation between the two cavity plating portions 140 and the two conductive filling portions 150. An insulating material 172′ may be filled in the disconnecting portion 141. A material of the second insulating layer 171 or the third insulating layer 172 shown in FIG. 1 may be filled in the disconnecting portion 141.

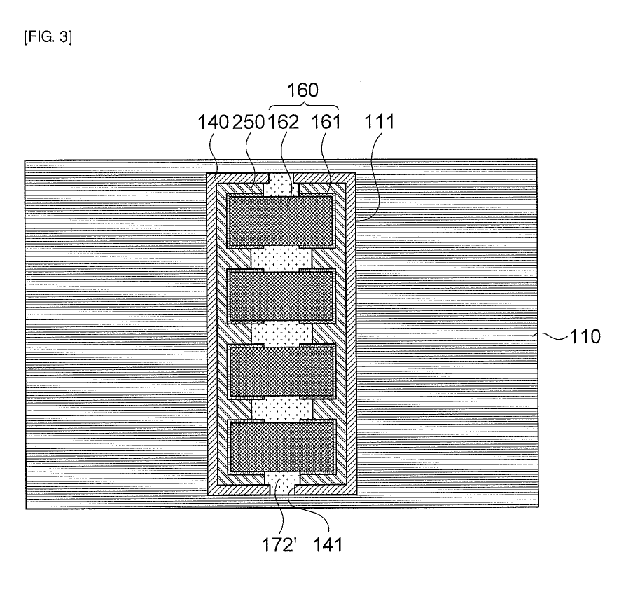

FIG. 3 is a plan view showing the surface taken along I-I′ of FIG. 1 in an electronic component embedded substrate 100 in accordance with another embodiment of the present invention.

Referring to FIG. 3, in the electronic component embedded substrate 100 in accordance with another embodiment of the present invention, a plurality of electronic components 160 may be inserted in a cavity 111. At this time, the plurality of electronic components 160 may be connected in parallel.

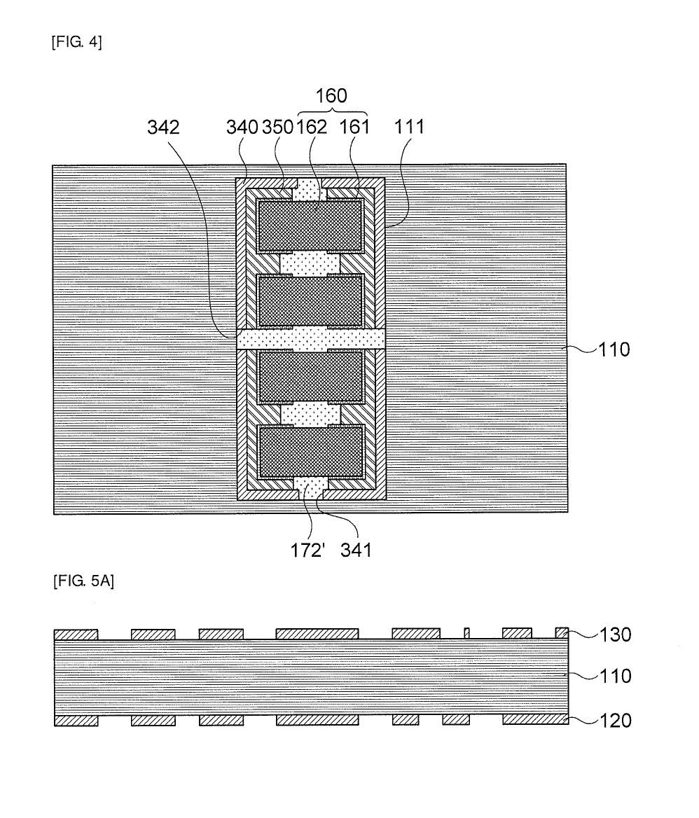

FIG. 4 is a plan view showing the surface taken along I-I′ of FIG. 1 in an electronic component embedded substrate 100 in accordance with still another embodiment of the present invention.

Referring to FIG. 4, in the electronic component embedded substrate 100 in accordance with still another embodiment of the present invention, a plurality of electronic components 160 may be inserted in a cavity 111, but it will be understood that all of the electronic components may not be connected in parallel and some of the electronic components may be connected in parallel.

As shown in FIGS. 3 and 4, it is possible to implement various capacitances according to the need using mass-produced standardized capacitors by connecting the electronic components 160, particularly capacitors in parallel in various combinations.

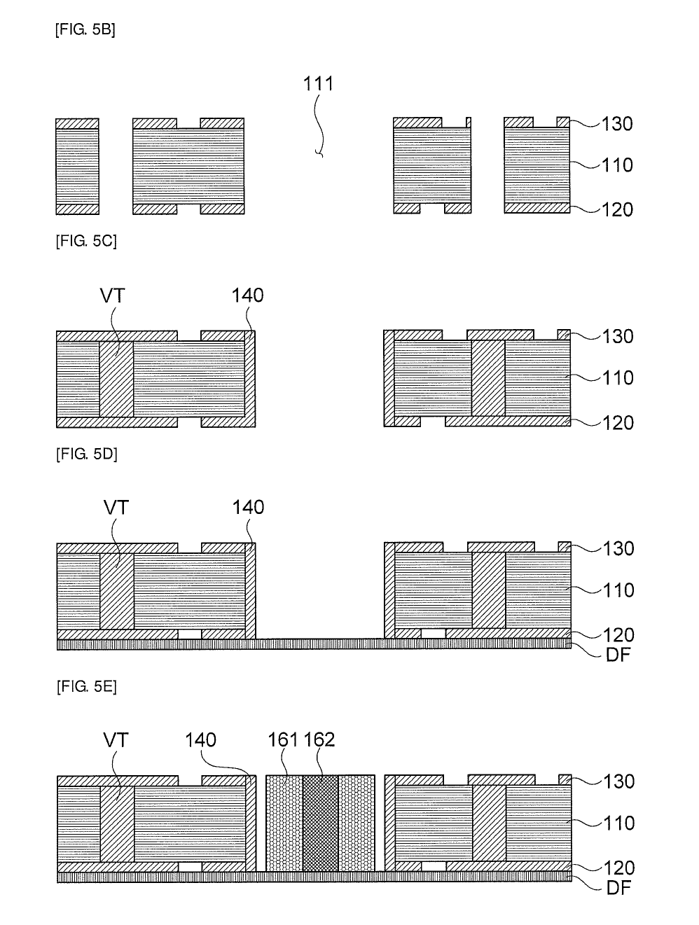

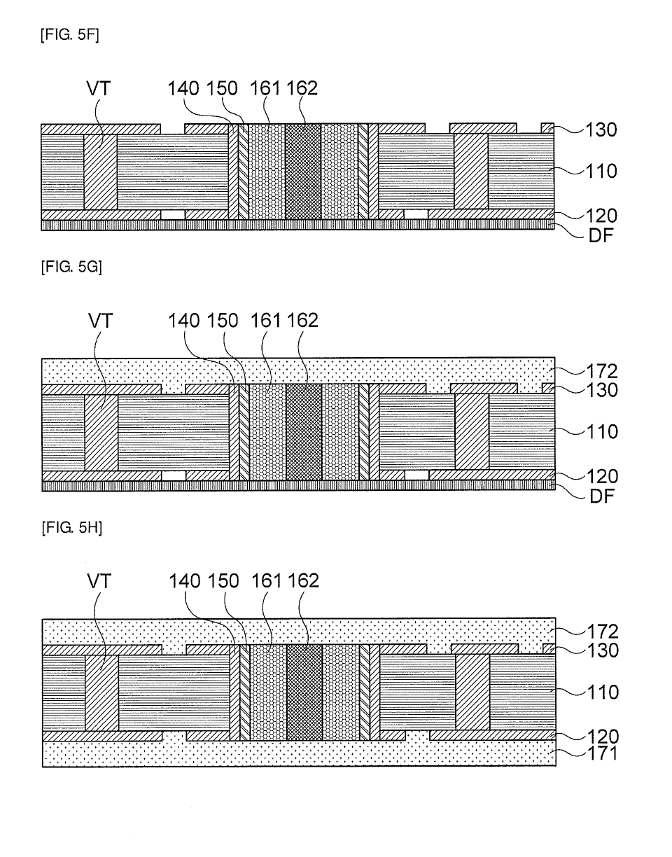

FIGS. 5a to 5i are process diagrams schematically showing a method of manufacturing an electronic component embedded substrate in accordance with an embodiment of the present invention.

Referring to FIGS. 5a and 5b, a cavity 111 is formed in a first insulating layer 110 using CO₂ laser, YAG laser, etc.

At this time, a first metal pattern 120 and a third metal pattern 130 may be formed on the first insulating layer 110.

Further, when processing the cavity 111 using CO₂ laser, the first metal pattern 120 or the second metal pattern 130 may perform a role of a mask.

Further, in this process, a through via hole for forming a through via VT may be processed.

Next, referring to FIG. 5c, a cavity plating portion 140 is formed on a surface of the cavity 111 formed in the first insulating layer 110.

Next, referring to FIGS. 5d and 5e, an electronic component 160 is inserted in the cavity 111 in a state in which a detach film DF is attached to the first metal pattern 120 to fix the electronic component 160 to the detach film DF.

Next, referring to FIG. 5f, a conductive filling portion 150 is formed by filling an insulating material in a space between the cavity plating portion 140 and the electronic component 160. At this time, the conductive filling portion 150 may not be formed when the cavity plating portion 140 and the electronic component 160 are in direct contact with each other.

In this state, it may be tested whether the electronic component 160 is well connected or whether there are disconnecting portions in the first and second metal patterns 120 and 130.

Next, referring to FIG. 5g, a third insulating layer 172 is formed on upper surfaces of the first metal pattern 120, the first insulating layer 110, the cavity plating portion 140, the conductive filling portion 150, and the electronic component 160. At this time, as shown in FIGS. 2 to 4, an insulating material such as resin may be filled in a disconnecting portion 141, and this insulating material may be used to implement the third insulating layer 172.

Next, referring to FIG. 5h, a second insulating layer 171 is formed by stacking an interlayer insulator after removing the detach film DF.

Next, referring to FIG. 5i, first to sixth vias V1 to V6, a first circuit pattern 181, and a second circuit pattern 182 are formed.

As shown, like the first via V1, the third via V3, and the fourth via V4, a via may be formed by processing a via hole in one area selected from the first metal pattern 120 or the second metal pattern 130, the cavity plating portion 140, the conductive filling portion 150, and an external electrode 161.

In the prior art, as the size of the electronic component 160 is reduced, it is difficult to process a via hole that accurately exposes the external electrode 161 of the electronic component 160, but according to the method of manufacturing an electronic component embedded substrate in accordance with an embodiment of the present invention, it will be understood that electrical connectivity of the electronic component 160 can be secured even when a via hole is processed in a wider area than the prior art.

In addition, when the electronic component 160 is a capacitor, since the cavity plating portion 140 and the external electrode 161 are in contact with each other over a wide area, low resistance can be implemented on a charge moving path of the electronic component 160 and connection reliability can be improved.

Meanwhile, although the foregoing explained the manufacturing process using a subtractive method as an example, the manufacturing process may be implemented by an additive method.

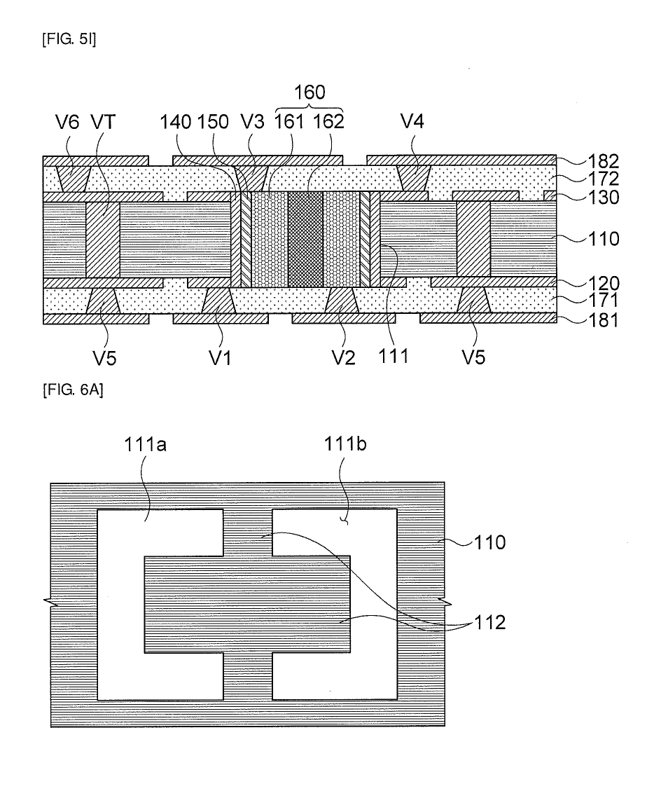

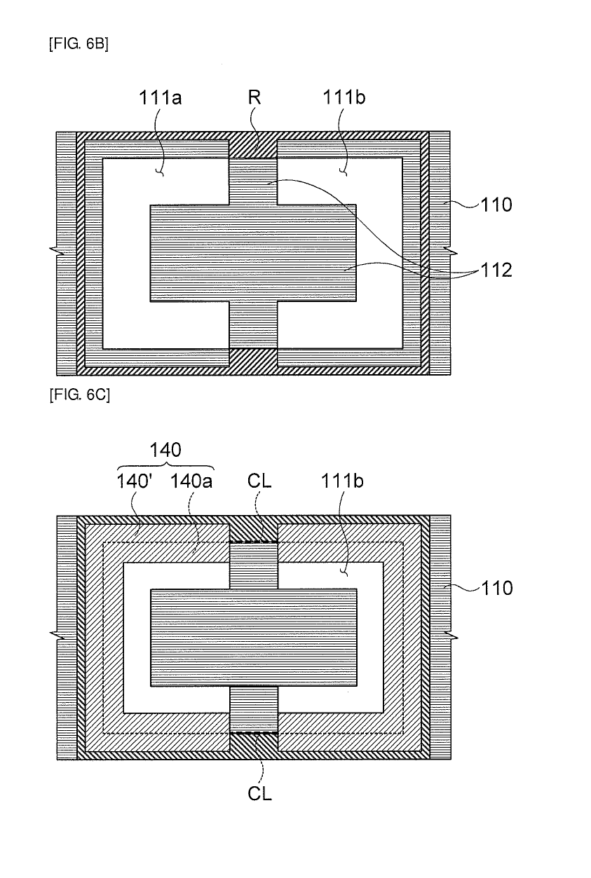

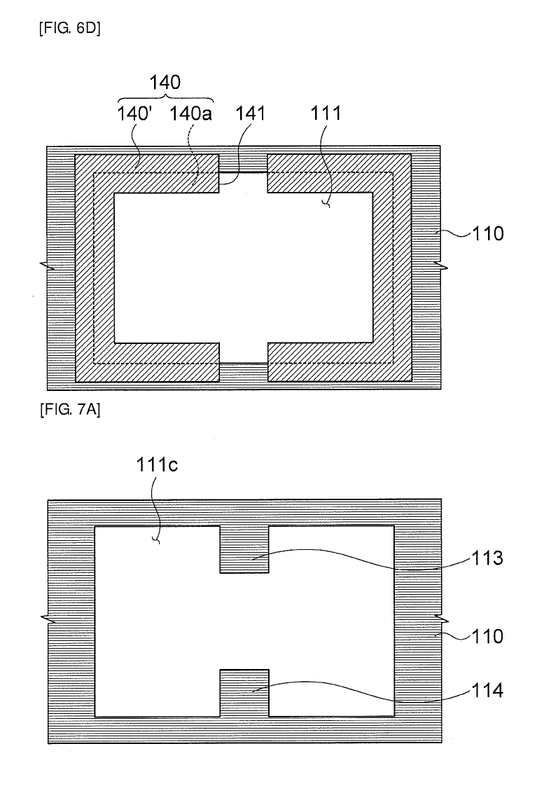

FIGS. 6a to 6d are process diagrams schematically showing the process of forming the cavity 111 having the cavity plating portion 140 in the first insulating layer 110 in the method of manufacturing an electronic component embedded substrate in accordance with an embodiment of the present invention.

First, referring to FIG. 6a, a first temporary cavity 111a and a second temporary cavity 111b are processed in the first insulating layer 110.

At this time, the first temporary cavity 111a may be formed in a “⊂” shape, and the second temporary cavity 111b may be formed in a horizontally reversed shape of the first temporary cavity 111a, that is, in a “⊃” shape.

Further, open directions of the first temporary cavity 111a and the second temporary cavity 111b may be formed to face each other so that a temporary remaining portion 112 may be formed between the first temporary cavity 111a and the second temporary cavity 111b.

Next, referring to FIGS. 6b and 6c, a resist portion R is formed to perform a plating process, and the cavity plating portion 140 is formed on the surface of the cavity 111 by electroless plating or electroplating.

Next, referring to FIGS. 6c and 6d, the temporary remaining portion 112 is removed along a cutting line CL and the resist portion R is also removed to form the cavity plating portion 140 having the disconnecting portion 141.

At this time, a plating portion 140′, which is formed in an area indicated by a dotted line, may perform a function of improving electrical connectivity between the second metal pattern and the cavity plating portion 140.

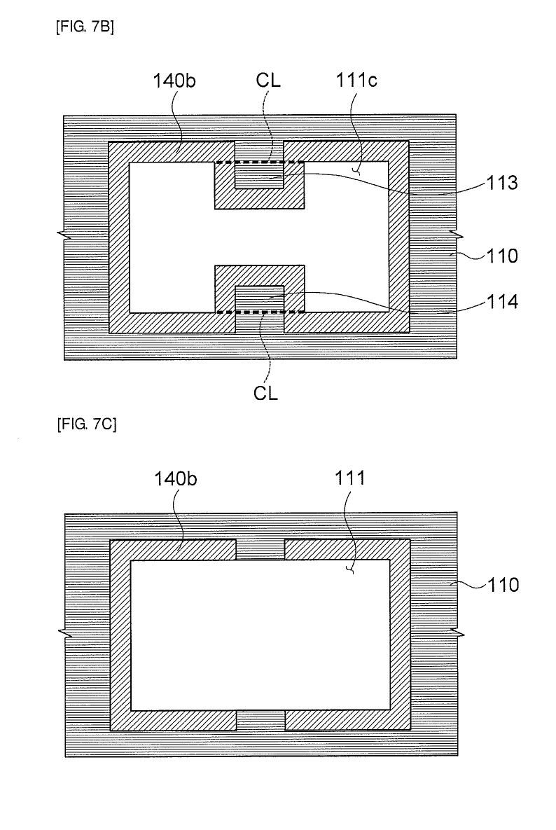

FIGS. 7a to 7c are process diagrams schematically showing a process of forming a cavity 111 having a cavity plating portion 140 in a first insulating layer 110 in a method of manufacturing an electronic component embedded substrate in accordance with another embodiment of the present invention.

First, referring to FIG. 7a, a third temporary cavity 111c having a first projecting portion 113 and a second projecting portion 114 is formed by processing a portion of a first insulating layer.

At this time, the first projecting portion 113 and the second projecting portion 114 may be symmetrically formed to face each other.

Next, referring to FIGS. 7b and 7c, a cavity plating portion 140 is formed by removing portions of the first projecting portion 113 and the second projecting portion 114 along a cutting line CL after plating a conductive material on a surface of the third temporary cavity 111c by electroless plating or electroplating.

Since the present invention configured as above can expand a permitted area with which a via for electrically connecting between an electronic component embedded in a substrate and an outer layer circuit pattern can be in contact even when the size of an external electrode of the electronic component is reduced than before, it is possible to overcome deterioration of electrical connectivity due to factors such as placing tolerance occurring when mounting an electronic component, via hole processing tolerance occurring when processing a via hole, and via hole size.

Further, since an electrical connection path to an electronic component embedded in a substrate is increased, it is possible to improve a charge moving speed between other elements electrically connected to the electronic component.

What is claimed is:

1. An electronic component embedded substrate having an electronic component embedded therein, comprising:
a cavity formed in at least one insulating layer provided inside the electronic component embedded substrate;
an electronic component having at least a portion inserted in the cavity; and
a cavity plating portion formed on a surface of the cavity opposite to at least one surface of the electronic component.

2. The electronic component embedded substrate according to claim 1, wherein an external electrode is provided on a side surface of the electronic component, and further comprising:
a conductive filling portion formed by filling a conductive material between the cavity plating portion and the external electrode to electrically connect between the cavity plating portion and the external electrode.

3. The electronic component embedded substrate according to claim 2, further comprising:
a via having one surface in contact with at least one area selected from at least a portion of the external electrode, at least a portion of the conductive filling portion, and at least a portion of the cavity plating portion.

4. The electronic component embedded substrate according to claim 3, wherein the external electrode consists of at least two electrodes provided on a surface of the electronic component to be separated from each other,
disconnecting portions are formed in the cavity plating portion connected to the electrodes to electrically isolate the electrodes from each other, and
a conductive filling portion is filled between the respective cavity plating portions and the respective electrodes electrically separated by the disconnecting portions.

5. The electronic component embedded substrate according to claim 4, wherein an insulating material is filled in a space between the electrodes, between the disconnecting portions, and between the conductive filling portions.

6. The electronic component embedded substrate according to claim 2, further comprising:
a metal pattern provided on a surface of the insulating layer and electrically connected to the cavity plating portion; and
a via having one surface in contact with at least one area selected from at least a portion of the external electrode, at least a portion of the conductive filling portion, at least a portion of the cavity plating portion, and at least a portion of the metal pattern.

7. The electronic component embedded substrate according to claim 6, wherein the external electrode consists of at least two electrodes provided on a surface of the electronic component to be separated from each other,
disconnecting portions are formed in the cavity plating portion connected to the electrodes to electrically isolate the electrodes from each other, and
a conductive filling portion is filled between the respective cavity plating portions and the respective electrodes electrically separated by the disconnecting portions.

8. The electronic component embedded substrate according to claim 7, wherein an insulating material is filled in a space between the electrodes, between the disconnecting portions, and between the conductive filling portions.

9. The electronic component embedded substrate according to claim 2, wherein a plurality of electronic components are inserted in the cavity, and at least two of the plurality of electronic components are connected in parallel.

10. The electronic component embedded substrate according to claim 1, wherein an external electrode is provided on a side surface of the electronic component, and the cavity plating portion and the external electrode are in contact with each other to be electrically connected to each other.

11. The electronic component embedded substrate according to claim 10, further comprising:
a via having one surface in contact with at least one area selected from at least a portion of the external electrode and at least a portion of the cavity plating portion.

12. The electronic component embedded substrate according to claim 11, wherein the external electrode consists of at least two electrodes provided on a surface of the electronic component to be separated from each other, and disconnecting portions are formed in the cavity plating portion connected to the electrodes to electrically isolate the electrodes from each other.

13. The electronic component embedded substrate according to claim 12, wherein an insulating material is filled in a space between the electrodes and between the disconnecting portions.

14. The electronic component embedded substrate according to claim 10, further comprising:
a metal pattern provided on a surface of the insulating layer and electrically connected to the cavity plating portion; and
a via having one surface in contact with at least one area selected from at least a portion of the external electrode, at least a portion of the cavity plating portion, and at least a portion of the metal pattern.

15. The electronic component embedded substrate according to claim 14, wherein the external electrode consists of at least two electrodes provided on a surface of the electronic component to be separated from each other, and disconnecting portions are formed in the cavity plating portion connected to the electrodes to electrically isolate the electrodes from each other.

16. The electronic component embedded substrate according to claim 15, wherein an insulating material is filled in a space between the electrodes and between the disconnecting portions.

17. The electronic component embedded substrate according to claim 10, wherein a plurality of electronic components are inserted in the cavity, and at least two of the plurality of electronic components are connected in parallel.

18. An electronic component embedded substrate in which an electronic component comprising a hexahedral body portion and two external electrodes which cover opposite surfaces of the body portion is embedded, comprising:
a cavity formed in at least one insulating layer provided inside the electronic component embedded substrate; and
a cavity plating portion formed on a surface of the cavity opposite to the external electrode.

19. An electronic component embedded substrate comprising:
a first insulating layer having a first metal pattern on a lower surface and a second metal pattern on an upper surface and comprising a cavity passing through the upper surface and the lower surface;
an electronic component having at least one external electrode on a surface and having at least a portion inserted in the cavity;
a cavity plating portion formed on a surface of the cavity opposite to the external electrode to be electrically connected to at least one of the first metal pattern and the second metal pattern;
a conductive filling portion formed by filling a conductive material between the cavity plating portion and the external electrode;
a second insulating layer for covering exposed surfaces of the first metal pattern, the first insulating layer, the cavity plating portion, the conductive filling portion, and the electronic component;
a first circuit pattern formed on a surface of the second insulating layer; and
a via having one surface in contact with at least one area selected from at least a portion of the external electrode, at least a portion of the conductive filling portion, at least a portion of the cavity plating portion, and at least a portion of the first metal pattern portion in contact with the cavity plating portion, and the other surface in contact with the first circuit pattern.

20. The electronic component embedded substrate according to claim 19, wherein the electronic component has at least two external electrodes formed in separated areas on a surface of the electronic component,
disconnecting portions are formed in the cavity plating portion connected to the external electrodes to electrically isolate the electrodes from each other, and
the conductive filling portion is filled between the respective cavity plating portions and the respective external electrodes electrically separated by the disconnecting portions.

21. The electronic component embedded substrate according to claim 20, wherein a material of the second insulating layer is filled in a space between the external electrodes, between the disconnecting portions, and between the conductive filling portions.

22. The electronic component embedded substrate according to claim 20, further comprising:
a fifth via having one surface in contact with at least a portion of the first metal pattern except the portion in contact with the cavity plating portion, and the other surface in contact with at least a portion of the first circuit pattern.

23. The electronic component embedded substrate according to claim 20, further comprising:
a third insulating layer for covering the exposed surfaces of the first insulating layer, the cavity plating portion, the conductive filling portion, and the electronic component;
a second circuit pattern formed on a surface of the third insulating layer; and
a third via having one surface in contact with at least one area selected from at least a portion of the external electrode, at least a portion of the conductive filling portion, at least a portion of the cavity plating portion, and at least a portion of the second metal pattern portion in contact with the cavity plating portion, and the other surface in contact with the second circuit pattern.

24. The electronic component embedded substrate according to claim 23, wherein at least one of a material of the first insulating layer and a material of the second insulating layer is filled in a space between the external electrodes, between the disconnecting portions, and between the conductive filling portions.

25. The electronic component embedded substrate according to claim 23, further comprising:
a sixth via having one surface in contact with at least a portion of the second metal pattern except the portion in contact with the cavity plating portion, and the other surface in contact with at least a portion of the second circuit pattern.

26. A method of manufacturing an electronic component embedded substrate having an electronic component embedded therein, comprising:
forming a cavity in at least one insulating layer provided inside the electronic component embedded substrate and forming a cavity plating portion by plating a conductive material on a surface of the cavity; and
inserting at least a portion of the electronic component in the cavity.

27. The method of manufacturing an electronic component embedded substrate according to claim 26, further comprising, after the inserting, filling a conductive material in a space between the electronic component and the cavity plating portion.

28. The method of manufacturing an electronic component embedded substrate according to claim 26, wherein the forming a cavity comprises:
forming a temporary remaining portion in a portion of the area in which the cavity is to be formed by processing a first temporary cavity having a “⊂” shape and a second temporary cavity having a shape symmetrical to the first temporary cavity to face each other while being separated from each other by a predetermined interval;
plating a conductive material on surfaces of the first temporary cavity and the second temporary cavity; and
removing the temporary remaining portion.

29. The method of manufacturing an electronic component embedded substrate according to claim 26, wherein the forming a cavity comprises:
forming a third temporary cavity in an area except a first projecting portion formed by projecting the insulating layer in the direction of a surface facing one surface of the cavity and a second projecting portion formed to be symmetrical to the first projecting portion on a surface facing the surface on which the first projecting portion is formed;
plating a conductive material on a surface of the third temporary cavity; and
removing portions of the first projecting portion and the second projecting portion.

30. A method of manufacturing an electronic component embedded substrate, comprising:
providing a first insulating layer having a first metal pattern on a lower surface and a second metal pattern on an upper surface;
forming a cavity in the first insulating layer and forming a cavity plating portion electrically connected to at least one of the first metal pattern and the second metal pattern by plating a conductive material on a surface of the cavity;
attaching a detach film to a lower surface of the first metal pattern;
attaching a lower surface of an electronic component to the detach film by inserting at least a portion of the electronic component having a plurality of external electrodes on a surface;
forming a conductive filling portion by filling a conductive material between the cavity plating portion and the external electrodes;
forming a third insulating layer by applying an insulating material on exposed surfaces of the second metal pattern, the first insulating layer, the cavity plating portion, the conductive filling portion, and the electronic component;
processing a via hole, which exposes at least one area selected from at least a portion of the external electrodes, at least a portion of the conductive filling portion, at least a portion of the cavity plating portion, and at least a portion of the second metal pattern portion in contact with the cavity plating portion, through the third insulating layer; and
filling a conductive material in the via hole and forming a second circuit pattern on an upper surface of the third insulating layer.

31. The method of manufacturing an electronic component embedded substrate according to claim 30, wherein the forming a cavity comprises:
forming a temporary remaining portion in a portion of the area in which the cavity is to be formed by processing a first temporary cavity having a “⊂”, shape and a second temporary cavity having a shape symmetrical to the first temporary cavity to face each other while being separated from each other by a predetermined interval;
plating a conductive material on surfaces of the first temporary cavity and the second temporary cavity; and
removing the temporary remaining portion.

32. The method of manufacturing an electronic component embedded substrate according to claim 30, wherein the forming a cavity comprises:
forming a third temporary cavity in an area except a first projecting portion formed by projecting the insulating layer in the direction of a surface facing one surface of the cavity and a second projecting portion formed to be symmetrical to the first projecting portion on a surface facing the surface on which the first projecting portion is formed;
plating a conductive material on a surface of the third temporary cavity; and
removing portions of the first projecting portion and the second projecting portion.

33. A method of manufacturing an electronic component embedded substrate, comprising:
providing a first insulating layer having a first metal pattern on a lower surface and a second metal pattern on an upper surface;
forming a cavity in the first insulating layer and forming a cavity plating portion electrically connected to at least one of the first metal pattern and the second metal pattern by plating a conductive material on a surface of the cavity;
attaching a detach film to a lower surface of the first metal pattern;
attaching a lower surface of an electronic component to the detach film by inserting at least a portion of the electronic component having a plurality of external electrodes on a surface;
forming a conductive filling portion by filling a conductive material between the cavity plating portion and the external electrodes;
forming a third insulating layer by applying an insulating material on exposed surfaces of the second metal pattern, the first insulating layer, the cavity plating portion, the conductive filling portion, and the electronic component;
forming a second insulating layer by applying an insulating material on the exposed surfaces of the first metal pattern, the first insulating layer, the cavity plating portion, the conductive filling portion, and the electronic component after removing a detach film;
forming a first via passing through the second insulating layer and a first circuit pattern provided on a lower surface of the second insulating layer to be connected to the first via; and
forming a third via passing through the third insulating layer and a second circuit pattern provided on an upper surface of the third insulating layer to be connected to the third via, wherein one surface of the first via is in contact with at least one area selected from at least a portion of the external electrodes, at least a portion of the conductive filling portion, at least a portion of the cavity plating portion, and at least a portion of the first metal pattern portion in contact with the cavity plating portion, and
one surface of the third via is in contact with at least one area selected from at least a portion of the external electrodes, at least a portion of the conductive filling portion, at least a portion of the cavity plating portion, and at least a portion of the second metal pattern portion in contact with the cavity plating portion.

34. The method of manufacturing an electronic component embedded substrate according to claim 33, wherein the attaching a lower surface of an electronic component is performed to attach the lower surface of the electronic component to the detach film by inserting a plurality of electronic components in the cavity.

35. The method of manufacturing an electronic component embedded substrate according to claim 34, wherein at least two of the plurality of electronic components are connected in parallel.
